(19) United States
(12) Patent Application Publication
(10) Pub. No.: US 2026/0144090 A1
(43) Pub. Date: May 21, 2026

(54) THREE-DIMENSIONAL LEADFRAME AND ASSOCIATED SEMICONDUCTOR PACKAGE

(71) Applicant: CYNTEC CO.,LTD, Hsinchu (TW)

(72) Inventors: Chun-Hao Chang, Hsinchu (TW); Yu-Lin Yang, Hsinchu (TW)

(73) Assignee: CYNTECCO.,LTD., Hsinchu (TW)

(21) Appl. No.: 19/203,198

(22) Filed: May 9, 2025

Related U.S. Application Data
(60) Provisional application No. 63/723,540, filed on Nov. 21, 2024.

(51) Int. Cl. H01L 23/495; H01L 21/48

(52) U.S. Cl. CPC H10W 70/442; H10W 70/042

(57) ABSTRACT

The present disclosure provides a package including a die, a first leadframe and a second leadframe. The first leadframe and the second leadframe are stacked and bonded together by using adhering substance to form a final leadframe. The die is bonded to the final leadframe. By using the package of the embodiments, the package includes appropriate signal transmission paths and multi-directional heat dissipation paths.

### CROSS REFERENCE TO RELATED APPLICATIONS

This application claims the benefit of U.S. Provisional Application No. 63/723,540, filed on Nov. 21, 2024. The content of the application is incorporated herein by reference.

### BACKGROUND OF THE DISCLOSURE

### 1. Field of the Disclosure

The present disclosure relates to a semiconductor package.

### 2. Description of the Prior Art

Leadframes have been a traditional and widely used interconnect technology in semiconductor packaging, providing both electrical connections and mechanical support for the die. However, with the increasing demands for higher performance, smaller form factors, and cost-effectiveness in electronic devices, the limitations of conventional leadframe-based packaging are becoming more apparent, particularly in the areas of signal integrity, manufacturing cost, and heat dissipation.

### SUMMARY OF THE DISCLOSURE

Therefore, one of the objectives of the present disclosure is to provide a three-dimensional leadframe and a related semiconductor package, which can offer improved signal transmission paths, better heat dissipation, and reasonable manufacturing costs, thereby addressing the problems described in the prior art.

According to one embodiment of the present disclosure, a package comprising a die, a first leadframe and a second leadframe is disclosed. The first leadframe and the second leadframe are stacked and bonded together by using adhering substance to form a final leadframe. The die is bonded to the final leadframe.

According to one embodiment of the present disclosure, a leadframe comprising a first leadframe and a second leadframe is disclosed. The first leadframe and the second leadframe are stacked and bonded together by using adhering substance to form a final leadframe.

According to one embodiment of the present disclosure, a method for manufacturing a leadframe comprises steps of: manufacturing a first leadframe; manufacturing a second leadframe; and stacking and bonding the first leadframe and the second leadframe to form a final leadframe serving as the leadframe.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating a semiconductor package according to one embodiment of the present disclosure.

FIG. 1B is a top view of a first leadframe according to one embodiment of the present disclosure.

FIG. 1C is a diagram showing the first leadframe and a second leadframe according to one embodiment of the present disclosure.

FIG. 2 is a diagram illustrating a portion of the final leadframe comprising the first leadframe and the second leadframe according to a first embodiment of the present disclosure.

FIG. 3 is a diagram illustrating a portion of the final leadframe comprising the first leadframe and the second leadframe according to a second embodiment of the present disclosure.

FIG. 4 is a diagram illustrating a portion of the final leadframe comprising the first leadframe and the second leadframe according to a third embodiment of the present disclosure.

FIG. 5 is a diagram illustrating a leadframe having a lock hole according to a first embodiment of the present disclosure.

FIG. 6 is a flowchart of manufacturing a final leadframe comprising a first leadframe and a second leadframe according to one embodiment of the present disclosure.

### DETAILED DESCRIPTION

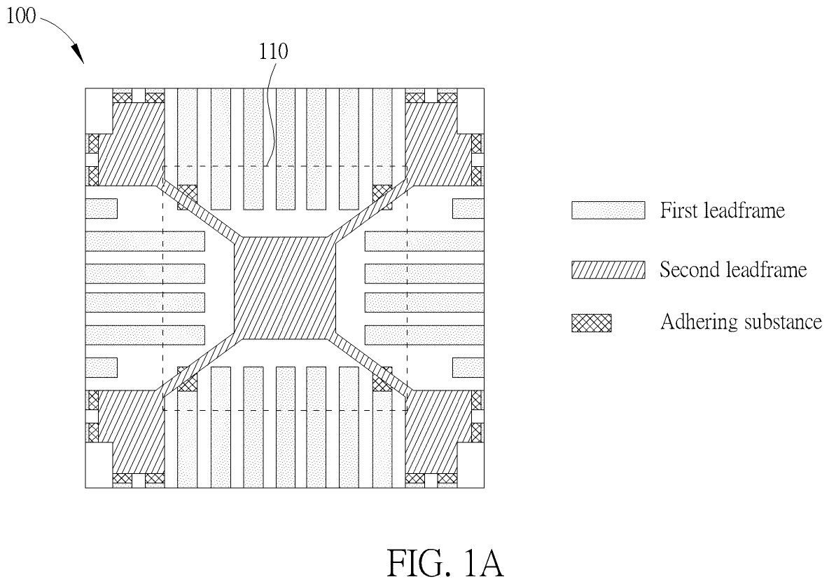

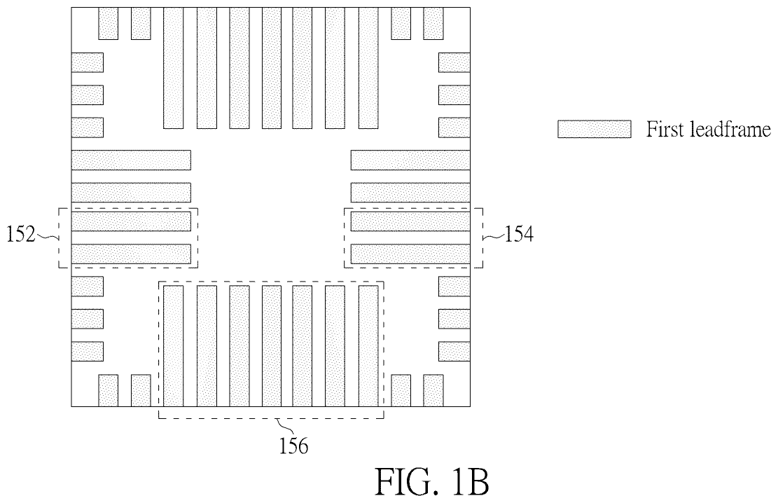

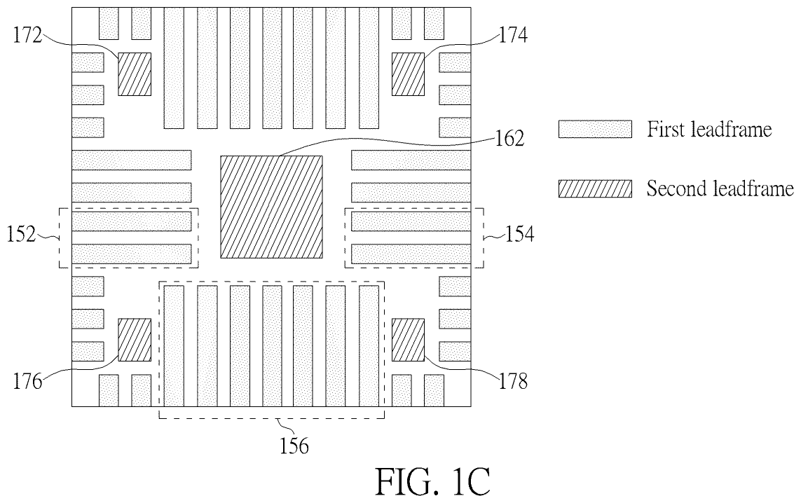

FIG. 1A is a diagram illustrating a semiconductor package 100 according to one embodiment of the present disclosure. As shown in FIG. 1A, the semiconductor package 100 comprises a first leadframe, a second leadframe and a die 110. In this embodiment, the first leadframe and the second leadframe are bonded together in a vertical direction (herein, “vertical direction” refers to the direction perpendicular to the plane of the paper), meaning the first leadframe and the second leadframe are stacked to form a final leadframe (i.e., three-dimensional leadframe) for subsequent die 110 assembly thereon. In this embodiment, the final leadframe comprising the first leadframe and the second leadframe serves as the physical and electrical interface between the die 110 and an external circuitry on a printed circuit board (PCB) or other system, wherein the leads on all four sides of the first leadframe are used to transmit signals from the die 100 to the external circuitry, or to transmit signals from the external circuitry to the die 110.

In this embodiment, both the first leadframe and the second leadframe are bonded together using adhering substance at the leadframe manufacturing plant, wherein the adhering substance may be solder paste, epoxy paste, film, pillar, etc. In addition, the adhering substance may be conductive or non-conductive. In one embodiment, a portion of the first leadframe and a portion of the second leadframe are bonded together via conductive adhering substance, while another portion of the first leadframe and another portion of the second leadframe are bonded together via non-conductive adhering substance.

In this embodiment, since the first leadframe and the second leadframe are bonded together in the vertical direction, the leadframe will have more signal transmission paths. That is, in addition to the traditional transmission paths in a planar direction, there are also multiple vertical signal transmission paths in FIG. 1A, so the signal transmission quality can be adjusted or improved. In addition, the final leadframe comprising the first leadframe and the second leadframe have additional thermal dissipation path, thus improving the heat dissipation problem of the semiconductor package 100.

It should be noted that the shapes of the first leadframe and the second leadframe shown in FIG. 1A are merely illustrative examples, and are not limitations of the present disclosure. In other embodiments, as long as the first leadframe and the second leadframe can be stacked and bonded together, they can have any suitable shape.

FIG. 1B is a top view of a first leadframe according to one embodiment of the present disclosure. As shown in FIG. 1B, considering the effects of Surface Mount Technology (SMT) and design rules, the first leadframe is designed with a symmetrical structure and fixed spacing between pins, as shown in FIG. 1B where the first leadframe has symmetrical leads. However, under this design, some space cannot be used as a heat dissipation path or signal transmission path because the power/ground routing cannot pass through, such as leads 152, 154 and 156 shown in FIG. 1B. To improve the limitations of the first leadframe in signal transmission and heat dissipation, the second leadframe of this embodiment provides additional signal transmission and heat dissipation paths.

Referring to FIG. 1C, a portion 162 of the second leadframe is directly connected to the die 110 so that the portion 162 can receive the heat generated by the die 110 during operation (another part of heat is received by the first frame), thereby enabling the leadframe to have better heat dissipation. In addition, portions 172, 174, 176 and 178 may provide signal transmission paths for the first leadframe, to solve the problem of limited signal paths in the first leadframe.

In one embodiment, because the second leadframe comprises additional signal transmission paths and heat dissipation paths, the number of leads of the first leadframe may be reduced to lower the area of the first leadframe.

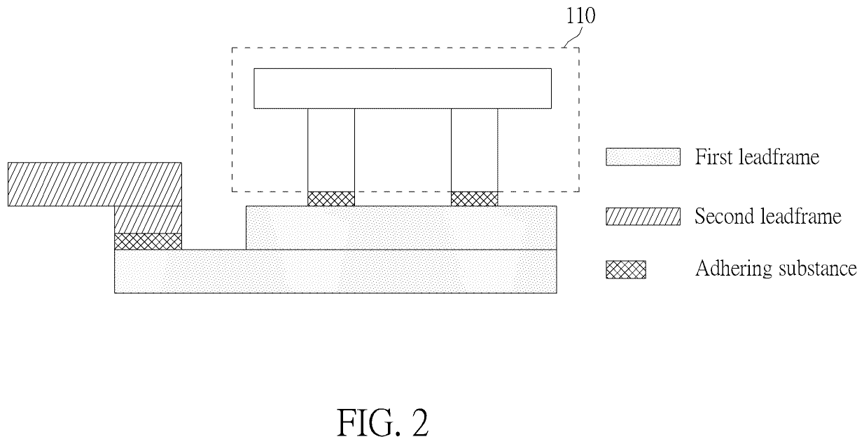

FIG. 2 is a diagram illustrating a portion of the final leadframe comprising the first leadframe and the second leadframe according to a first embodiment of the present disclosure. As shown in FIG. 2, the first leadframe comprises stepped structure, wherein the die 110 is bonded to the upper layer of the stepped structure, and the second leadframe is bonded to the lower layer of the stepped structure.

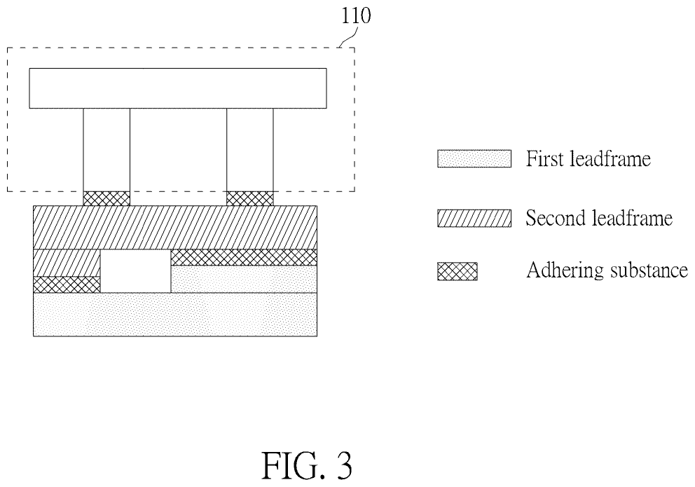

FIG. 3 is a diagram illustrating a portion of the final leadframe comprising the first leadframe and the second leadframe according to a second embodiment of the present disclosure. As shown in FIG. 3, the first leadframe comprises a stepped structure, and the second leadframe also comprises a stepped structure (inverted, which can be referred to as a inverted stepped structure), wherein the upper layer of the second leadframe's stepped structure is bonded to the lower layer of the first leadframe's stepped structure, and the upper layer of the first leadframe's stepped structure is bonded to the lower layer of the second leadframe's stepped structure. In addition, the die 110 is bonded to the second leadframe by using adhering substance.

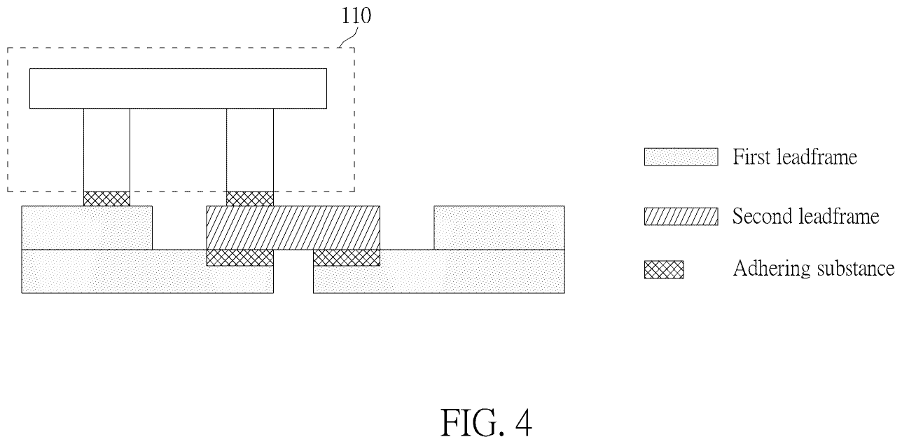

FIG. 4 is a diagram illustrating a portion of the final leadframe comprising the first leadframe and the second leadframe according to a third embodiment of the present disclosure. As shown in FIG. 4, the first leadframe is bonded to lower layers of two stepped structures of the second leadframe, and the die 110 is bonded to the second leadframe and the first leadframe by using adhering substance.

In the above embodiments shown in FIG. 2, FIG. 3 and FIG. 4, the adhering substance used to bond the die, the first leadframe and the second leadframe can be designed to be conductive or non-conductive based on the designer's considerations, so that the final leadframe has appropriate signal transmission paths. In addition, by using the above embodiments, the final leadframe can have multi-directional heat dissipation paths, thus providing a good heat dissipation effect.

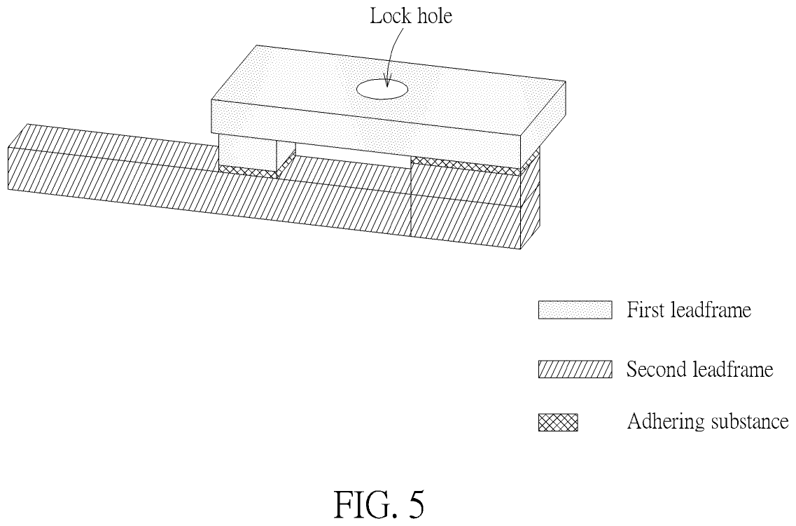

In one embodiment, at least one of the first leadframe and the second leadframe comprises a lock hole (mold lock hole), wherein the lock hole is used to securely position the leadframe within the molding tool (mold) during the molding process, or for the following die assemble process. FIG. 5 shows that the first leadframe is a porous leadframe comprising lock holes.

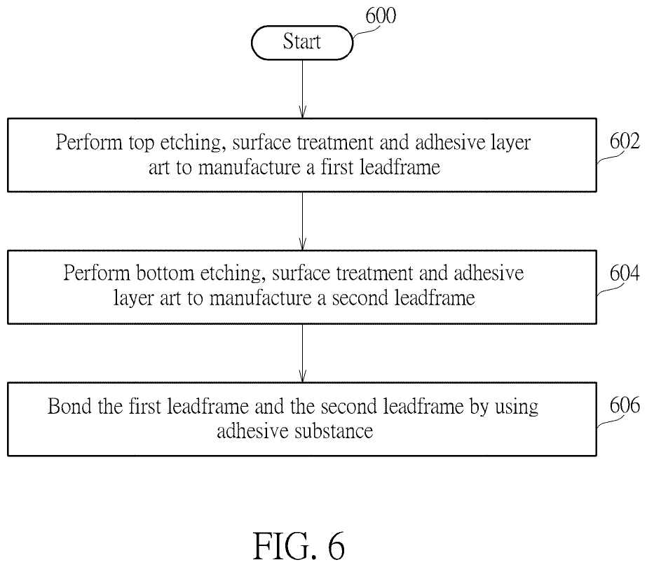

FIG. 6 is a flowchart of manufacturing a final leadframe comprising a first leadframe and a second leadframe according to one embodiment of the present disclosure. In Step 600, the flow starts. In Step 602, a metal sheet or strip, made by copper, copper alloys, iron-nickel alloys or other suitable materials, is processed under top etching, surface treatment and adhesive layer art to manufacture a first leadframe. Specifically, the top etching process is used to remove metal from the metal sheet or strip to create the desired leadframe pattern. The photochemical etching is commonly used for high-precision leadframes, and the photochemical etching comprises the following typical steps: material cleaning, photoresist coating, exposure, development, etching, photoresist stripping, cleaning and inspection. After the first leadframe is etched and cleaned, it undergoes various surface treatments to enhance its properties and ensure reliable performance in the semiconductor package 100. These treatments can improve wire bonding, die attachment, corrosion resistance, and adhesion to the molding compound. Common surface treatments include the following steps: cleaning, plating, roughening, chemical conversion coating, self-assembled monolayers (SAMs) and passivation. It is noted that the operations of top etching process and surface treatments are known by a person skilled in the art, so further descriptions are omitted here. In addition, the adhesive layer art is performed to apply adhering substance such as epoxy or other polymer to the first leadframe, for the first leadframe to bond to the die 110 and/or the second leadframe.

In Step 604, a metal sheet or strip, made by copper, copper alloys, iron-nickel alloys or other suitable materials, is processed under bottom etching, surface treatment and adhesive layer art to manufacture a second leadframe. Specifically, the bottom etching process is used to remove metal from the metal sheet or strip to create the desired leadframe pattern. After the first leadframe is etched and cleaned, it undergoes various surface treatments to enhance its properties and ensure reliable performance in the semiconductor package 100. In addition, the adhesive layer art is performed to apply adhering substance such as epoxy or other polymer to the second leadframe, for the second leadframe to bond to the die 110 and/or the first leadframe.

In Step 606, the first leadframe and the second leadframe are stacked and bonded together by using adhering substance, to manufacture the final leadframe.

After the final leadframe is successfully manufactured, the die 110 is then bonded to the final leadframe. Then, series of steps are performed to ensure the functionality and reliability of the semiconductor package 100, such as wire bonding, molding, trim and form, marking, testing and final packaging. Because the above-mentioned post-die attach processes in semiconductor package are known by a person skilled in the art, further descriptions are omitted here.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A package, comprising:
a die; and
a first leadframe and a second leadframe, wherein the first leadframe and the second leadframe are stacked and bonded together by using adhering substance to form a final leadframe;
wherein the die is bonded to the final leadframe.

2. The package of claim 1, wherein the first leadframe comprises a stepped structure, the die is bonded to an upper layer of the stepped structure, and the second leadframe is bonded to a lower layer of the stepped structure.

3. The package of claim 1, wherein the first leadframe comprises a first stepped structure, and the second leadframe comprises a second stepped structure, an upper layer of the second stepped structure is bonded to a lower layer of the first stepped structure, and an upper layer of the first stepped structure is bonded to a lower layer of the second stepped structure.

4. The package of claim 3, wherein a portion of the die is bonded on the second leadframe.

5. The package of claim 1, wherein the second leadframe is bonded to lower layers of two stepped structures of the first leadframe, and a portion of the die is bonded to the second leadframe and the first leadframe.

6. A leadframe, comprising:
a first leadframe; and
a second leadframe, wherein the first leadframe and the second leadframe are stacked and bonded together by using adhering substance to form a final leadframe.

7. The leadframe of claim 6, wherein the first leadframe comprises a stepped structure, an upper layer of the stepped structure is used to be bonded with a die, and the second leadframe is bonded to a lower layer of the stepped structure.

8. The leadframe of claim 6, wherein the first leadframe comprises a first stepped structure, and the second leadframe comprises a second stepped structure, an upper layer of the second stepped structure is bonded to a lower layer of the first stepped structure, and an upper layer of the first stepped structure is bonded to a lower layer of the second stepped structure.

9. The leadframe of claim 8, wherein a portion of the second leadframe is used to be bonded to a die.

10. The leadframe of claim 6, wherein the second leadframe is bonded to lower layers of two stepped structures of the first leadframe.

11. A method for manufacturing a leadframe, comprising:
manufacturing a first leadframe;
manufacturing a second leadframe; and
stacking and bonding the first leadframe and the second leadframe to form a final leadframe serving as the leadframe.

12. The method of claim 11, wherein the first leadframe comprises a stepped structure, an upper layer of the stepped structure is used to be bonded with a die, and the second leadframe is bonded to a lower layer of the stepped structure.

13. The method of claim 11, wherein the first leadframe comprises a first stepped structure, and the second leadframe comprises a second stepped structure, an upper layer of the second stepped structure is bonded to a lower layer of the first stepped structure, and an upper layer of the first stepped structure is bonded to a lower layer of the second stepped structure.

14. The method of claim 13, wherein a portion of the second leadframe is used to be bonded to a die.

15. The method of claim 11, wherein the second leadframe is bonded to lower layers of two stepped structures of the first leadframe.

16. The method of claim 11, wherein the step of manufacturing the first leadframe and the step of manufacturing the second leadframe comprise:
performing a top etching, a surface treatment and an adhesive layer art to manufacture the first leadframe; and
performing a bottom etching, the surface treatment and the adhesive layer art to manufacture the second leadframe.
